(19) United States
(12) Patent Application Publication
(10) Pub. No.: US 2024/0113498 A1
(43) Pub. Date: Apr. 4, 2024

(54) SEMICONDUCTOR LASER

(71) Applicant: Lumentum Japan, Inc., Sagamihara (JP)

(72) Inventor: Atsushi NAKAMURA, Nagano (JP)

(21) Appl. No.: 18/129,661

(22) Filed: Mar. 31, 2023

(30) Foreign Application Priority Data
Sep. 30, 2022 (JP) 2022-158314
Jan. 16, 2023 (JP) 2023-004481

(51) Int. Cl. H01S 5/02257; H01S 5/028; H01S 5/12; H01S 5/227

(52) U.S. Cl. CPC H01S 5/02257; H01S 5/028; H01S 5/124; H01S 5/227; H01S 5/34

(57) ABSTRACT

Some implementation described herein provide a semiconductor laser that is excellent in side mode suppression ratio (SMSR) yield. The semiconductor laser includes: a substrate; a mesa structure formed on the substrate to include a diffraction grating layer and an active layer, the diffraction grating layer including a phase shift portion; a window structure arranged between both ends of the mesa structure in a longitudinal direction thereof and both facets of the semiconductor laser; and a low-reflection facet coating film formed on the both facets, and an effective refractive index of the window structure is lower than an effective refractive index of the active layer.

### CROSS-REFERENCE TO RELATED APPLICATIONS

This Patent application claims priority to Japanese patent application number 2022-158314 filed on Sep. 30, 2022, and to Japanese patent application number 2023-004481 filed on Jan. 16, 2023, the contents of which are hereby incorporated by reference into this application.

### TECHNICAL FIELD

The present disclosure relates generally to a semiconductor laser.

### BACKGROUND

Semiconductor lasers are widely used as a light source to be used in optical communications. A distributed feedback semiconductor laser (DFB laser) is one type of a semiconductor laser. The DFB laser includes a diffraction grating. Further, a window structure can be used to suppress return light that has been reflected by facets.

### SUMMARY

A semiconductor laser includes an active layer for generating light. Wavelengths of the light beams generated by the active layer have some width. A grating is arranged so that a light having a specific wavelength intensely oscillates. Further, when a phase shift structure is employed in the diffraction grating, the light can oscillate at a single wavelength. In many cases, it is preferred that an intensity ratio between the specific wavelength and another wavelength be large as a signal source for optical communications. This intensity ratio is called “side mode suppression ratio (SMSR).” The SMSR is influenced by a phase state of light reflection at a facet of the semiconductor laser. Thus, when laser light is reflected at the facet, in some cases, a desired SMSR cannot be obtained due to, for example, variations in resonator length. As a method of preventing reflection at the facets, there is a structure in which a low-reflection facet coating film (hereinafter referred to as “AR film”) is formed on the facets. However, in some cases, the reflection at the facets cannot be suppressed enough due to, for example, variations in manufacture of the AR film to generate a defect in SMSR, thereby causing an increase in cost of the semiconductor laser.

Some implementations described herein provide a semiconductor laser that reduces reflection of light at facets.

In some implementations, a semiconductor laser includes: a substrate; a mesa structure formed on the substrate to include a diffraction grating layer and an active layer, the diffraction grating layer including a phase shift portion; a window structure arranged between both ends of the mesa structure in a longitudinal direction thereof and both facets of the semiconductor laser; and a low-reflection facet coating film formed on the both facets, wherein an effective refractive index of the window structure is lower than an effective refractive index of the active layer.

In some implementations, a semiconductor laser that is excellent in SMSR yield is provided.

### BRIEF DESCRIPTION OF THE DRAWINGS

FIG. 1 is a top view for illustrating a semiconductor laser according to a first example implementation of the present invention.

FIG. 2 is a schematic sectional view for illustrating the semiconductor laser of FIG. 1 taken along the line II-II.

FIG. 3 is a schematic sectional view for illustrating the semiconductor laser of FIG. 1 taken along the line III-III.

FIG. 4 is a top view for illustrating a semiconductor laser according to a second example implementation of the present invention.

FIG. 5 is a schematic sectional view for illustrating the semiconductor laser of FIG. 4 taken along the line V-V.

FIG. 6 is a top view for illustrating a semiconductor laser according to a third example implementation of the present invention.

FIG. 7 is a schematic sectional view for illustrating the semiconductor laser of FIG. 6 taken along the line VII-VII.

FIG. 8 is a schematic sectional view for illustrating the semiconductor laser of FIG. 6 taken along the line VIII-VIII.

FIG. 9 is a schematic sectional view for illustrating the semiconductor laser of FIG. 6 taken along the line IX-IX.

### DETAILED DESCRIPTION

Some implementations are specifically described in detail in the following with reference to drawings. In the drawings, the same members are denoted by the same reference numerals and have the same or equivalent functions, and a repetitive description thereof may be omitted for the sake of simplicity. Note that, the drawings referred to in the following are only for illustrating the example implementations, and are not necessarily drawn to scale.

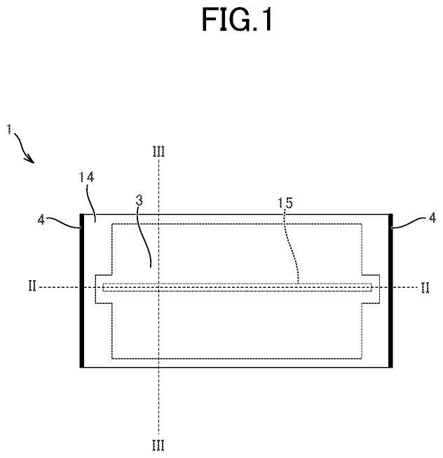

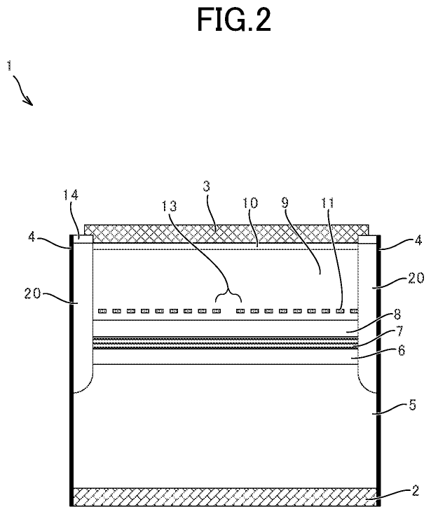

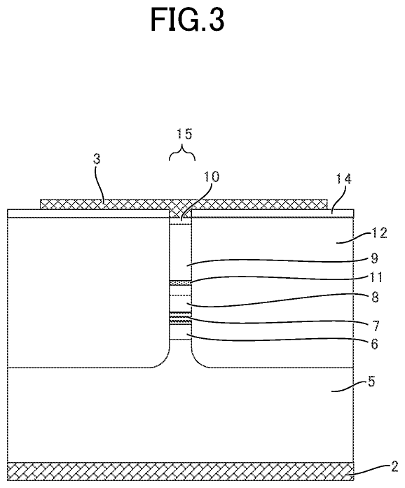

FIG. 1 is a top view for illustrating a semiconductor laser 1 according to a first example implementation of the present invention. FIG. 2 shows a schematic sectional view taken along the line II-II of FIG. 1. FIG. 3 shows a schematic sectional view taken along the line of FIG. 1. The semiconductor laser 1 may include a first electrode 2 on a back surface thereof and a second electrode 3 on a front surface thereof. The first electrode 2 and the second electrode 3 may be metal layers. A light may be emitted from a facet through injection of a current between the first electrode 2 and the second electrode 3. In the following, a facet refers to a surface of the semiconductor laser 1 in a longitudinal direction of a mesa structure 15 which is described later (facets are on surfaces in a right-and-left direction of FIG. 1). In the first example implementation, a low-reflection facet coating film 4 (hereinafter referred to as “AR film 4”) may be formed on two facets. In this case, the AR film 4 may be a multilayer insulating film designed such that a reflectance with respect to a wavelength of the light emitted by the semiconductor laser 1 becomes less than 1%. The reflectance may be merely an example, and, in this case, a coating film having a reflectance of 5% or less may be referred to as “AR film.”

The semiconductor laser 1 may include a semiconductor layer in which an optical confinement layer (SCH layer) 6 of a first conductivity type, an active layer 7, an optical confinement layer (SCH layer) 8 of a second conductivity type, a cladding layer 9 of the second conductivity type, and a contact layer 10 of the second conductivity type are formed in the stated order on a substrate 5 of the first conductivity type. Further, the cladding layer 9 of the second conductivity type may have a diffraction grating layer 11 formed therein. A buffer layer may be formed between the substrate 5 and the SCH layer 6 of the first conductivity type. The buffer layer may be a layer formed of the same material as that of the substrate 5 and may have the same conductivity type as that of the substrate 5, and hence the buffer layer may be substantially integrated with the substrate 5. Herein, when the substrate is referred to, the buffer layer may be also included in the structure of the substrate. The substrate 5 may also function as a cladding layer of the first conductivity type. The semiconductor laser 1 may be a DFB laser. The active layer 7 may be formed of, for example, a multiple-quantum well layer. Further, the multiple-quantum well layer may be an intrinsic semiconductor or an n-type semiconductor. Accordingly, the first conductivity type may be an n-type and the second conductivity type may be a p-type, but the first conductivity type may be the p-type and the second conductivity type may be the n-type. Further, the semiconductor layers described above may have the mesa structure 15. A lowermost portion of the mesa structure 15 may be formed of a part of the substrate 5. That is, the mesa structure 15 may be formed on the substrate 5 to include the diffraction grating layer 11 and the active layer 7, the diffraction grating layer 11 including a phase shift portion 13. A buried layer 12 may be formed on both sides of the mesa structure 15 in a transverse direction thereof. Both sides of the mesa structure 15 may be each covered by the buried layer 12 having a semi-insulating property. The buried layer 12 may be a stack formed of semiconductor layers of the p-type and the n-type.

The diffraction grating layer 11 may be arranged in the longitudinal direction of the mesa structure 15. A diffraction grating period of the diffraction grating layer 11 may be constant. However, the diffraction grating layer 11 may include the phase shift portion 13 at a substantially center portion thereof when seen in the longitudinal direction of the mesa structure 15. In this case, the phase shift portion 13 may be a 214 phase shift portion. The position and shift amount of the phase shift portion 13 are merely examples.

The semiconductor laser 1 may have an insulating film 14 on a front surface. The insulating film 14 may cover the front surface of the semiconductor laser 1 except for the vicinity of an upper surface of the mesa structure 15. The second electrode 3 may be electrically and physically in contact with the contact layer 10 of the second conductivity type in a region above the mesa structure 15, on which the insulating film 14 is not arranged.

The semiconductor laser 1 may include a window structure 20 formed between an end portion of the mesa structure 15 and the facet on which the AR film 4 is formed. The window structures 20 may be arranged between both ends of the mesa structure 15 in the longitudinal direction and both facets on which the AR film 4 is formed. The window structure 20 may be a semiconductor layer having an effective refractive index lower than that of the active layer 7. In this case, the window structure 20 may be a semi-insulating semiconductor layer formed of the same material as that of the buried layer 12. Further, for example, the window structure 20 may be formed of the same material as that of the substrate 5. The window structure 20 may have a different polarity from that of the substrate 5. For example, the substrate 5 may be of a conductivity type, whereas the window structure 20 may have a semi-insulating property. The window structure 20 may be formed of a material different from that of the buried layer 12. A side portion of the window structure 20 on the mesa structure 15 side may be in contact with a part of the substrate 5, the SCH layer 6 of the first conductivity type, the active layer 7, the SCH layer 8 of the second conductivity type, the cladding layer 9 of the second conductivity type, and the contact layer 10 of the second conductivity type. In this case, a height of the window structure 20 (a distance from an upper surface of the contact layer 10 of the second conductivity type to the substrate 5) substantially matches a height of the buried layer 12 (a distance from an upper surface of the substrate 5 to an upper surface of the buried layer 12). When the height of the window structure 20 and the height of the buried layer 12 may be set to be the same, the window structure 20 and the buried layer 12 may be formed in the same step, with the result that manufacturing becomes easier. Further, a bottom portion of the window structure 20 may be in contact with the substrate 5.

Even when the AR film 4 is formed on the facets, some of the laser light may be reflected by the facets. The light which has been reflected and returns to the active layer 7 may cause a reduction in SMSR yield. Accordingly, the semiconductor laser 1 may include the window structures 20 at both facets. The effective refractive index of the window structure 20 may be lower than the effective refractive index of the mesa structure 15, and hence the light emitted through the mesa structure 15 spreads in the window structures 20. Most of the spread light may be emitted to an outside without being reflected by the facets, due to to the AR films 4. However, some of the light beams may be reflected by the facets and return to the window structures 20 side. Specifically, the light may be spread by the window structures 20, thereby being capable of suppressing the reflected light which return to the active layer 7. Thus, the reduction in SMSR yield can be suppressed. Moreover, in the first example implementation, the window structure 20 and the AR film 4 may be arranged on the both facets, and hence the light which return to the active layer 7 is significantly reduced.

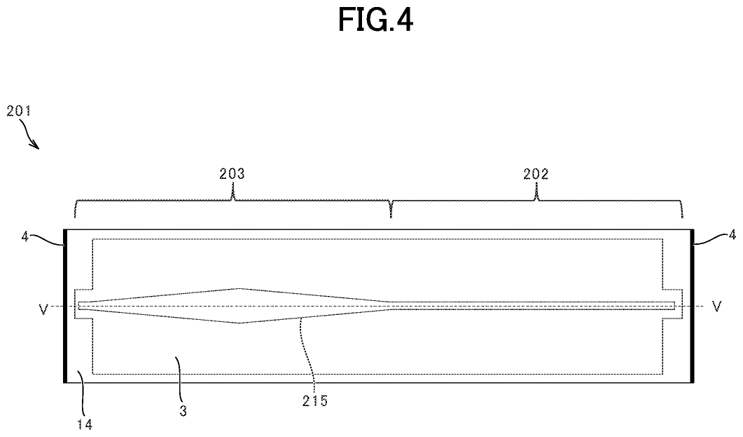

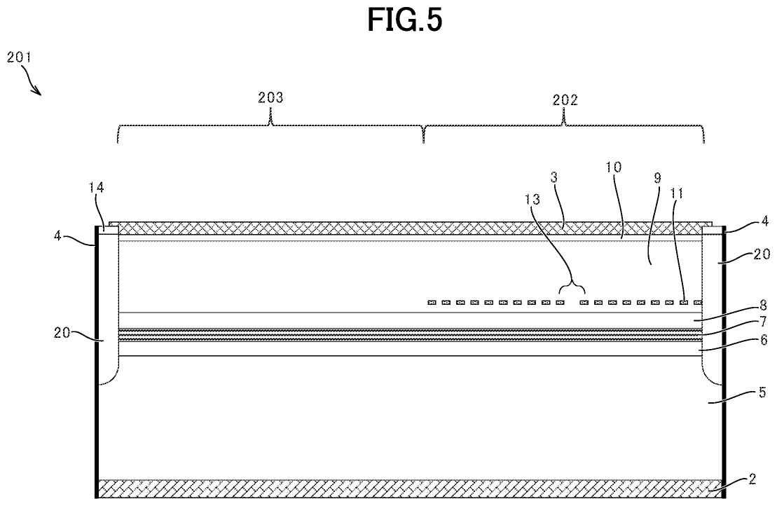

FIG. 4 is a top view for illustrating a semiconductor laser 201 according to a second example implementation of the present invention. FIG. 5 shows a schematic sectional view taken along the line V-V of FIG. 4. The second example implementation may be different from the first example implementation in that an optical amplifier portion 203 may be arranged on one side of a laser portion 202 in a longitudinal direction thereof.

The semiconductor laser 201 may be a semiconductor optical amplifier integrated laser into which the laser portion 202 and the optical amplifier portion 203 may be integrated. The multilayer structure of the laser portion 202 may be the same as that of the semiconductor laser 1 of the first example implementation. The optical amplifier portion 203 may have the same multilayer structure as that of the laser portion 202 except that the optical amplifier portion 203 does not include the diffraction grating layer 11. Further, a width of the mesa structure 215 in the optical amplifier portion 203 may be larger than a width of the mesa structure 215 in the laser portion 202. Specifically, the width of the mesa structure 215 may not be constant, and may become larger as a distance from the laser portion 202 increases and becomes smaller toward the facet on a side opposite to the laser portion 202. Further, each of the first electrode 2 and the second electrode 3 extends over the laser portion 202 and the optical amplifier portion 203 to serve as an electrode for both of the laser portion 202 and the optical amplifier portion 203. Accordingly, in this structure, the same current may be injected into the laser portion 202 and the optical amplifier portion 203. The window structure 20 and the AR film 4 may be formed on the both facets of the semiconductor laser 1.

The optical amplifier portion 203 amplifies the light oscillated by the laser portion 202. The width of the mesa structure 215 may be increased so as to increase an amplification factor. However, when the width of the mesa structure 215 is increased, a far field pattern (FFP) of the emitted light may change, which may reduce an optical coupling ratio with an externally arranged lens. Accordingly, the width of the mesa structure 215 may be decreased toward the facet. In this case, the width of the mesa structure 215 at a portion at which the mesa structure 215 and the window structure 20 are in contact with each other and the width of the mesa structure 215 at a portion at which the laser portion 202 and the optical amplifier portion 203 are in contact with each other may be the same. However, the widths are not limited to this example.

The optical amplifier portion 203 amplifies also the light which has been reflected and returns to the active layer 7. Thus, when the window structures 20 are not arranged, the influence of the light which has been reflected and returns to the active layer 7 is large, and hence the SMSR yield is reduced. In the second example implementation, the reflected light is liable to enter the active layer 7 due to the window structures 20, thereby being capable of suppressing the reduction in SMSR yield.

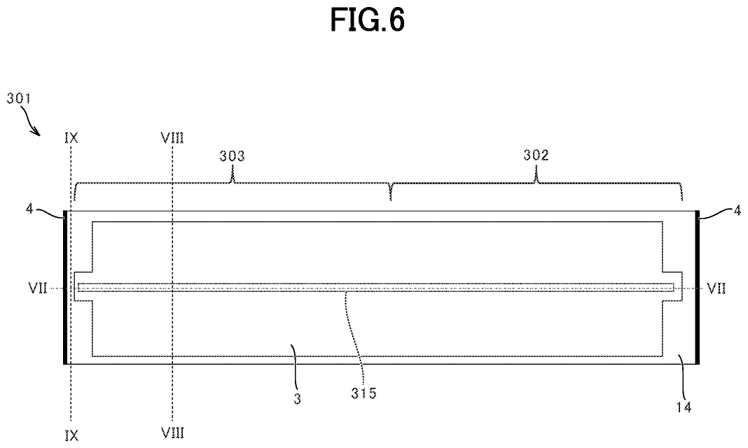

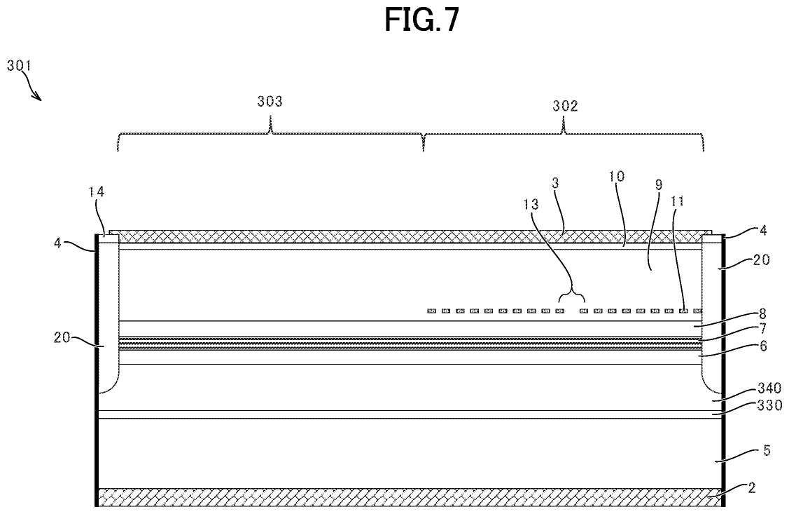

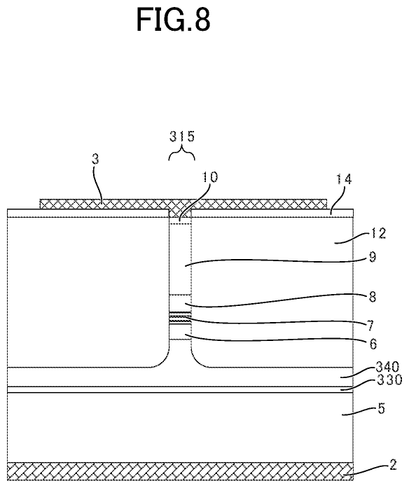

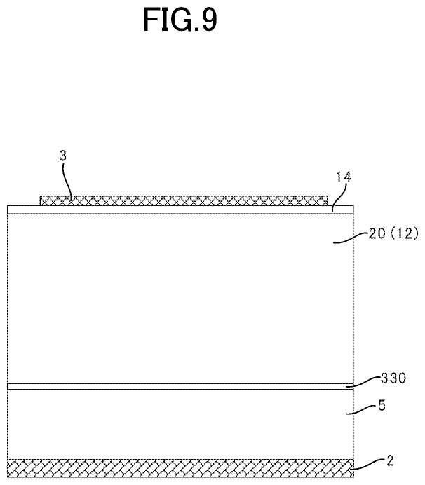

FIG. 6 is a top view for illustrating a semiconductor laser 301 according to a third example implementation of the present invention. FIG. 7 shows a schematic sectional view taken along the line VII-VII of FIG. 6. FIG. 8 shows a schematic sectional view taken along the line VIII-VIII of FIG. 6. FIG. 9 shows a schematic sectional view taken along the line IX-IX of FIG. 6.

The semiconductor laser 301 may be a semiconductor optical amplifier integrated laser into which a laser portion 302 and an optical amplifier portion 303 may be integrated. The semiconductor laser 301 may have the same structure as that of the semiconductor laser 201 of the second example implementation except that a width of a mesa structure 315 in the optical amplifier portion 303 may be constant and that the semiconductor laser 301 may include a high refractive index layer 330 and a cladding layer 340 of the first conductivity type.

The high refractive index layer 330 may be arranged below the mesa structure 315 and the buried layers 12. The high refractive index layer 330 extends to both facets. As illustrated in FIG. 7, the window structures 20 may be arranged so as to avoid the high refractive index layer 330. In other words, the bottom portion of the window structure 20 may be arranged above the high refractive index layer 330. The high refractive index layer 330 may be a semiconductor layer having a higher effective refractive index than those of the substrate 5 and the window structure 20. The cladding layer 340 of the first conductivity type may be arranged between the high refractive index layer 330 and the SCH layer 6 of the first conductivity type. The cladding layer 340 of the first conductivity type may be a layer formed of the same material as that of the substrate 5 and may have the same conductivity type as that of the substrate 5, but the configuration is not limited thereto. A lowermost portion of the mesa structure 315 may be formed of a part of the cladding layer 340 of the first conductivity type.

Further, the diffraction grating layer 11 is may not be in contact with the high refractive index layer 330. The diffraction grating layer 11 may be formed separately from the high refractive index layer 330, and hence may have a high degree of freedom in design. It may be preferred that a width of the high refractive index layer 330 be larger than the width of the mesa structure 315. It may be only required that the high refractive index layer 330 overlap at least a part of each of the buried layers 12, and it is not required that the high refractive index layer 330 overlap the entire buried layers 12.

The high refractive index layer 330 may have an effect of bringing the light spread mainly through the active layer 7 toward the substrate 5 side. As described above, the light emitted through the active layer 7 (mesa structure 315) may be spread in the window structure 20. Among the spread light, the light directed toward the insulating film 14 side may be reflected by, for example, the insulating film 14 or the second electrode 3. The reflected light beam becomes a scattered light, which disturbs the shape of the FFP of the emitted light of the semiconductor laser 301. The disturbance of the shape of the FFP causes a reduction in coupling efficiency with respect to an external optical component 8 (for example, a lens). In the third example implementation, the high refractive index layer 330 may be arranged below the window structures 20. The high refractive index layer 330 may have a higher effective refractive index than that of the window structure 20. Accordingly, the light may be brought closer to the high refractive index layer 330 side. As a result, reflection of light at an upper part such as at the insulating film 14 may be reduced, thereby being capable of suppressing the disturbance of the FFP shape. In this case, the high refractive index layer 330 extends to the facets. Thus, the light that is guided in the vicinity of the high refractive index layer 330 may be reflected by the facet and then returns to the high refractive index layer 330. In this case, the active layer 7 and the diffraction grating layer 11 may be major factors for determining the SMSR, and hence the light which may have been reflected by the facet and returns to the high refractive index layer 330 has almost no effect on the SMSR yield. Accordingly, also in the third example implementation, the reduction in SMSR yield may be suppressed. The high refractive index layer 330 may be combined with the semiconductor laser 1 of the first example implementation.

Due to the high refractive index layer 330 having a high refractive index, light distribution may be expanded. With this, a high-order lateral mode cut-off width (hereinafter referred to as “cut-off width”) may be increased, an area of a near field pattern (NFP) may be increased, and a spread angle of the FFP may be decreased, thereby improving an output characteristic and reliability. Specifically, as compared to the second example implementation in which the high refractive index layer 330 is not provided, in the third example implementation in which the high refractive index layer 330 is provided, refractive indices in regions on both sides of a region in which light beams are collected intensively are increased. As a result, a difference in refractive index is reduced between the region in which light is collected intensively and the regions on both sides thereof. When the difference in refractive index is reduced, the cut-off width is increased. When the cut-off width is increased, it is possible to increase a mesa width without generating a high-order mode in a lateral direction, thereby being capable of decreasing a current density in the multiple-quantum well layer. As a result, the reliability is increased and more currents can be injected, thereby being capable of achieving high output and high reliability.

According to some example implementations, the reduction in SMSR yield may be suppressed in the semiconductor laser in which the AR film may be formed on both facets, and which may include the diffraction grating layer including the phase shift portion. Suppression of the reduction in SMSR yield is achieved by providing the window structure on the both facets. Although the AR film has an anti-reflection effect, some light is reflected by the facets and return to the active layer. The light which return to the active layer causes the reduction in SMSR yield. Through arrangement of the window structure on the both facets, the light which return from the both facets to the active layer are suppressed, to thereby reduce the reduction in SMSR yield. The window structure has a higher effective refractive index than that of the active layer. The semiconductor laser may be an integrated semiconductor laser into which the laser portion and the optical amplifier portion are integrated. Further, a high refractive index layer having a higher effective refractive index than that of the window structure may be arranged below the window structure.

While there have been described what are at present considered to be certain embodiments of the invention, it will be understood that various modifications may be made thereto, and it is intended that the appended claims cover all such modifications as fall within the true spirit and scope of the invention.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A semiconductor laser, comprising:
a substrate;
a mesa structure formed on the substrate to include a diffraction grating layer and an active layer, the diffraction grating layer including a phase shift portion;
a window structure arranged between both ends of the mesa structure in a longitudinal direction thereof and both facets of the semiconductor laser; and
a low-reflection facet coating film formed on the both facets,
wherein an effective refractive index of the window structure is lower than an effective refractive index of the active layer.

2. The semiconductor laser according to claim 1, further comprising a buried layer formed on both sides of the mesa structure in a transverse direction thereof.

3. The semiconductor laser according to claim 2, wherein the window structure is formed of the same material as a material of the buried layer.

4. The semiconductor laser according to claim 3, wherein the window structure and the buried layer have the same depth.

5. The semiconductor laser according to claim 1, further comprising:
a laser portion including the diffraction grating layer; and
an optical amplifier portion arranged on one side of the laser portion in the longitudinal direction.

6. The semiconductor laser according to claim 5, wherein a width of the mesa structure in the optical amplifier portion is larger than a width of the mesa structure in the laser portion.

7. The semiconductor laser according to claim 1,
wherein a lowermost portion of the mesa structure is formed of a part of the substrate, and
wherein a bottom portion of the window structure is in contact with the substrate.

8. The semiconductor laser according to claim 1, further comprising a high refractive index layer which is arranged on a side of the substrate with respect to the mesa structure and the window structure, and has a higher effective refractive index than the effective refractive index of the window structure.

9. The semiconductor laser according to claim 8, wherein a width of the high refractive index layer is larger than a width of the mesa structure.

10. The semiconductor laser according to claim 8, wherein the window structure is arranged to avoid the high refractive index layer.
